(19) United States
(12) Patent Application Publication
(10) Pub. No.: US 2013/0162925 A1
(43) Pub. Date: Jun. 27, 2013

(54) Thin-film Transistor Substrate and Manufacturing Method Thereof and Liquid Crystal Display Device

(71) Applicant: Jun Wang, Shenzhen (CN)

(72) Inventor: Jun Wang, Shenzhen (CN)

(73) Assignee: SHENZHEN CHINA STAR OPTOELECTRONICS TECHNOLOGY CO. LTD, Shenzhen (CN)

(21) Appl. No.: 13/510,931

(22) PCT Filed: Mar. 2, 2012
(86) PCT No.: PCT/CN2012/071836

§ 371 Date: May 18, 2012

(30) Foreign Application Priority Data
Dec. 21, 2011 (CN) 201110433181.3

(51) Int. Cl. G02F 1/136; H01L 29/786; H01L 21/336

(52) U.S. Cl. 349/43; 438/585; 257/57; 257/E29.273

(57) ABSTRACT

The present invention provides a TFT substrate and manufacturing method thereof and a liquid crystal display device. The method includes: sequentially depositing a dielectric layer, a first metal layer, and a first semiconductor layer on a substrate; applying half-toning technique to form a first photoresist layer; removing portions of the dielectric layer, the first metal layer and the first semiconductor layer and making a portion of the dielectric layer exposed; removing the first photoresist layer and sequentially forming a second semiconductor layer, a first protection layer, and a second metal layer on the substrate; forming a second photoresist layer; removing all the layers on the substrate that are not covered; and removing the second photoresist layer and forming a second protection layer. The invention uses only two masking processes of half-toning and regular mask. The number of masking process is reduced and the manufacturing of TFT substrate is greatly simplified.

### BACKGROUND OF THE INVENTION

1. Field of the Invention

The present invention relates to the field of liquid crystal displaying techniques, and in particular to a thin-film transistor (TFT) substrate and manufacturing method thereof and a liquid crystal display device.

2. The Related Arts

Generally speaking, a manufacturing process of thin-film transistor liquid crystal display (TFT-LCD) comprises TFT array engineering, cell engineering, and module engineering, of which the TFT array engineering generally forms TFT circuits that are arranged in an array on a glass substrate.

The conventional TFT circuit requires five masking processes for completing the manufacture of TFT. With the need of large-sized panel, the size of masking process used to make the large-sized panels is also increased. The number and the expense of the mask used for large-sized panel makes it not possible to reduce the cost. Further, the masking process also involve delicate steps of photoresist coating, soft baking, hard baking, exposure, development, etching, and removal of photoresist, all these taking a great amount of processing time

In view of these problems, reducing masking process and the number of masks used are important technical issues to be handled by the industry.

### SUMMARY OF THE INVENTION

The technical issue to be addressed by the present invention is to provide a thin-film transistor (TFT) substrate and manufacturing method thereof and a liquid crystal display device in order to reduce masking process and the number of masks used and thus simplifying the manufacturing of substrate.

To address the above technical issue, the present invention adopts a technical solution that provides a method for manufacturing thin-film transistor (TFT) substrate, comprising the following steps: sequentially depositing a dielectric layer, a first metal layer, and a first semiconductor layer on a substrate; applying half-toning technique to form a thickness variable first photoresist layer on the first semiconductor layer; removing portions of the dielectric layer, the first metal layer and the first semiconductor layer that are not covered by the first photoresist layer and making surface of portion of the dielectric layer corresponding to a thin area of the first photoresist layer exposed; removing the first photoresist layer and sequentially forming a second semiconductor layer, a first protection layer, and a second metal layer on the substrate, in which the second metal layer is used to form TFT and gate line; forming a second photoresist layer on a portion of the second metal layer corresponding to the TFT and gate line; removing all layers on the substrate that are covered by the second photoresist layer except the dielectric layer at one side; and removing the second photoresist layer and forming a second protection layer on the substrate.

Wherein, the step of applying half-toning technique to form a thickness variable first photoresist layer on the first semiconductor layer comprises: applying half-toning to a first zone of the first photoresist layer and a second zone of the first photoresist layer that are spaced on the first semiconductor layer, wherein the first photoresist layer of the second zone has variable thickness.

Wherein, the step of removing portions of the dielectric layer, the first metal layer and the first semiconductor layer that are not covered by the first photoresist layer comprises: etching off portions of the dielectric layer, the first metal layer and the first semiconductor layer that are not covered by the first zone and the second zone of the first photoresist layer; performing ashing operation to such an extent that a thin portion of the first photoresist layer in the second zone is removed; and sequentially performing dry etching and wet etching to remove portions of the first metal layer and the first semiconductor layer that are not covered by the first photoresist layer in the second zone to expose a corresponding portion of the dielectric layer.

Wherein, the step of removing all layers on the substrate that are covered by the second photoresist layer except the dielectric layer at one side comprises: except the dielectric layer at one side, removing all layers that not covered by the second photoresist layer on the substrate by sequentially applying wet etching and dry etching.

Wherein, the dielectric layer is an indium tin oxide glass layer, the first semiconductor layer is an amorphous silicon layer doped with n+ impurity, the second semiconductor layer is an amorphous layer, and the first protection layer and the second protection layer are both silicon nitride layers.

To address the above technical issue, the present invention adopts another technical solution that provides a thin-film transistor (TFT) substrate, characterized by comprising: a dielectric layer, which is formed on the substrate and comprises a first zone dielectric layer and a second zone dielectric layer, the first zone dielectric layer and the second zone dielectric layer forming therebetween a channel; a first metal layer, which is formed on the dielectric layer; a first semiconductor layer, which is formed on the first metal layer; a second semiconductor layer, which is formed on the first semiconductor layer and the channel; a first protection layer, which is formed on the second semiconductor layer; a second metal layer, which is formed on the first protection layer; and a second protection layer, which covers the second metal layer and a surface of the substrate outside the second metal layer.

Wherein, the dielectric layer is an indium tin oxide glass layer.

Wherein, the first semiconductor layer is an amorphous silicon layer doped with n+ impurity and the second semiconductor layer is an amorphous layer.

Wherein, the first protection layer and the second protection layer are both silicon nitride layers.

To address the above technical issue, the present invention adopts a further technical solution that provides a liquid crystal display device, which comprises a color filter substrate and a thin-film transistor substrate that are substantially parallel and spaced.

Wherein the thin-film transistor substrate comprises: a substrate; a dielectric layer, which is formed on a surface of the substrate adjacent to the color filter substrate and comprises a first zone dielectric layer and a second zone dielectric layer, the first zone dielectric layer and the second zone dielectric layer forming therebetween a channel; a first metal layer, which is formed on the dielectric layer; a first semiconductor layer, which is formed on the first metal layer; a second semiconductor layer, which is formed on the first semiconductor layer and the channel; a first protection layer, which is formed on the second semiconductor layer; a second metal layer, which is formed on the first protection layer; and a second protection layer, which covers the second metal layer and a surface of the substrate outside the second metal layer.

Wherein, the dielectric layer is an indium tin oxide glass layer.

Wherein, the first semiconductor layer is an amorphous silicon layer doped with n+ impurity and the second semiconductor layer is an amorphous layer.

Wherein, the first protection layer and the second protection layer are both silicon nitride layers.

The efficacy of the present invention is that the present invention uses only two masking processes of half-toning and regular mask so that the number of masking process is reduced and the manufacturing of thin-film transistor substrate is greatly simplified.

### BRIEF DESCRIPTION OF THE DRAWINGS

FIG. 1 is a flow chart illustrating a method for manufacturing thin-film transistor (TFT) substrate according to an embodiment of the present invention;

FIG. 2 is a schematic view showing formation of a dielectric layer, a first metal layer, and a semiconductor layer in the manufacturing process of TFT substrate according to the present invention;

FIG. 3 is a schematic view showing formation of a first photoresist layer in the manufacturing process of TFT substrate according to the present invention;

FIG. 4 is a schematic view showing etching portions that are not covered by the first photoresist layer in the manufacturing process of TFT substrate according to the present invention;

FIG. 5 is a schematic view showing performance of ashing operation in the manufacturing process of TFT substrate according to the present invention;

FIG. 6 is a schematic view showing performance of etching operation in the manufacturing process of TFT substrate according to the present invention;

FIG. 7 is a schematic view showing removal of the first photoresist layer in the manufacturing process of TFT substrate according to the present invention;

FIG. 8 is a schematic view showing formation of a second semiconductor layer, a first protection layer, and a second metal layer in the manufacturing process of TFT substrate according to the present invention;

FIG. 9 is a schematic view showing formation of a second photoresist layer in the manufacturing process of TFT substrate according to the present invention;

FIG. 10 is a schematic view showing etching portions that are not covered by the second photoresist layer in the manufacturing process of TFT substrate according to the present invention;

FIG. 11 is a schematic view showing removal of the second photoresist layer in the manufacturing process of TFT substrate according to the present invention;

FIG. 12 is a schematic view showing formation of a second protection layer in the manufacturing process of TFT substrate according to the present invention;

FIG. 13 is a cross-sectional view showing the structure of a TFT substrate according to an embodiment of the present invention; and

FIG. 14 is a schematic plan view of a pixel included in the TFT substrate according to the present invention.

### DETAILED DESCRIPTION OF THE PREFERRED EMBODIMENTS

A detailed description of the present invention will be given with reference to the attached drawings and embodiments.

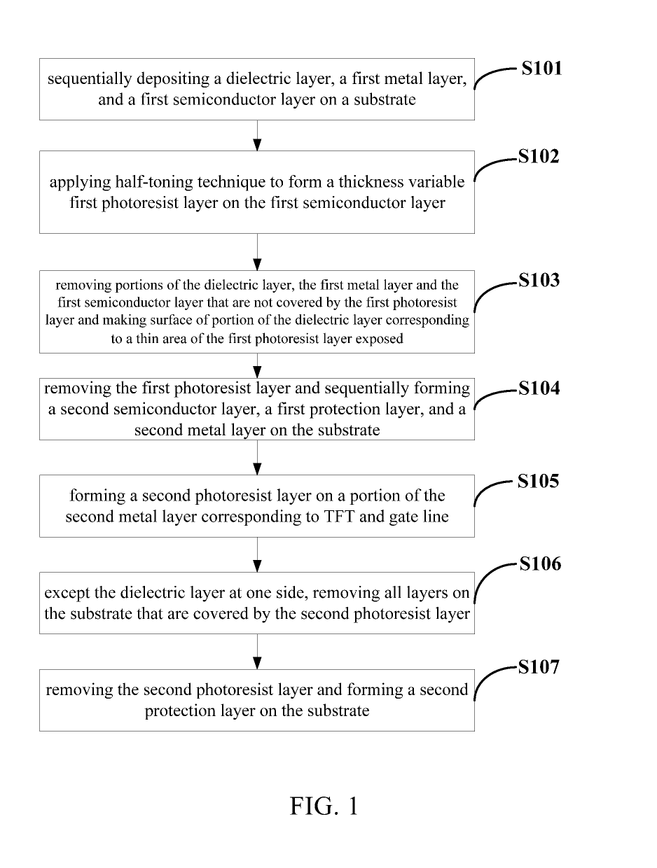

FIG. 1 is a flow chart illustrating a method for manufacturing thin-film transistor (TFT) substrate according to an embodiment of the present invention. As shown in FIG. 1, the method for manufacturing TFT substrate according to the instant embodiment comprises the following steps:

Step S101: sequentially depositing a dielectric layer, a first metal layer, and a first semiconductor layer on a substrate.

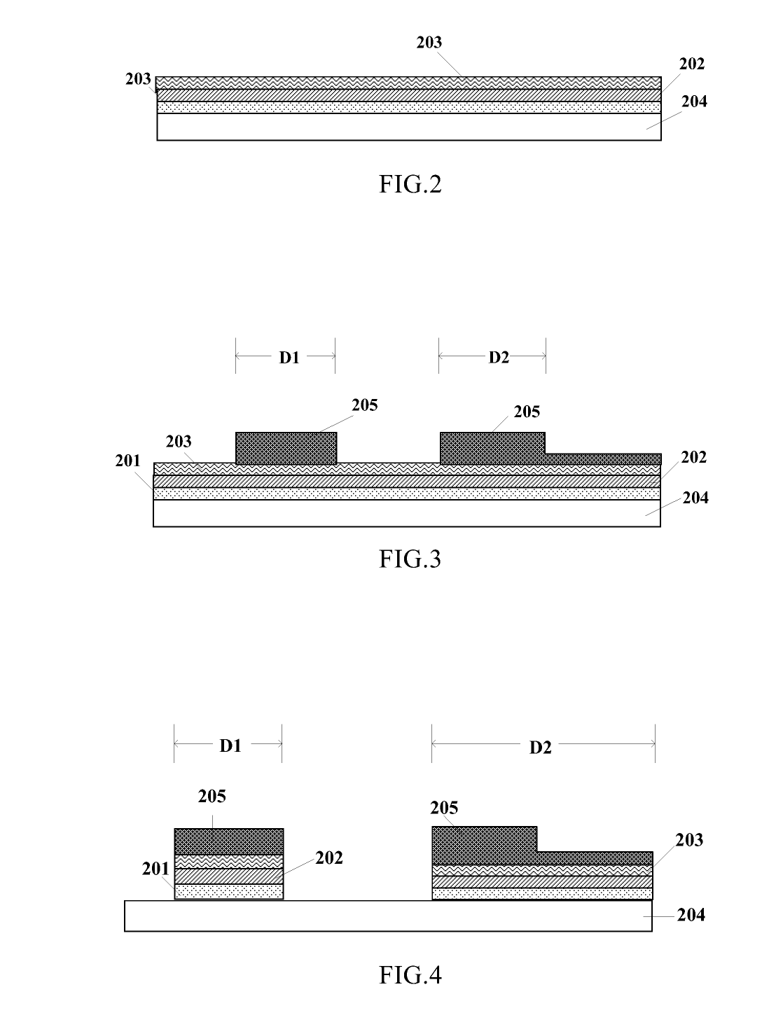

In Step S101, as shown in FIG. 2, the first semiconductor layer 204 can be a glass substrate, a plastic substrate, or a flexible substrate. The dielectric layer 201 is an indium tin oxide (ITO) glass layer, or it can be silicon oxide, silicon nitride, or a combination thereof. The first metal layer 202 is made of a metal, such as aluminum, molybdenum, titanium, chromium, copper, or an oxide of any of these metals, such as titanium oxide, or an alloy of these metals or other electrically conductive material. The first semiconductor layer 203 is an amorphous layer doped with n+ impurity.

Step S102: applying half-toning technique to form a thickness variable first photoresist layer on the first semiconductor layer.

In Step S102, as shown in FIG. 3, after the formation of the first semiconductor layer 203, a first photoresist layer 205 is subsequently formed on the first semiconductor layer 203. The first photoresist layer 205 is formed with a first mask process by applying half-tone technique. Through different light transmittance applied to various areas in the exposure process with half-toning technique, the first photoresist layer 205 is formed with local areas having different thickness. The first photoresist layer 205 comprises a first zone D1 and the second zone D2, and the first zone D1 and the second zone D2 are spaced from each other with a channel defined therebetween. The first zone D1 defines source pattern of the TFT. The first photoresist layer 205 in the second zone D2 have variable thickness, of which a thick area defines drain pattern of the transistor and a thin area provides means for partially exposing the dielectric layer 201.

In the instant embodiment, the half-toning technique comprises: using semi-transmittance mask to perform half-toning, namely half gray scale mask technique. Before exposure, the data for making a template are processed to form an exposure data diagram. Then, a mask (namely photo mask) is set so that exposure of the photoresist is carried out with the mask according to the exposure data diagram. After exposure, one development process and one etching process are performed and then washing and ashing of the mask are carried out.

In the instant embodiment, by using the half-toning technique, a single exposure operation may provide three exposure results of exposure portion, semi-exposure portion, and non-exposure portion that may be done in regular mask manufacturing process and photoresist of two different thickness can be formed, whereby the steps of operation for transferring image to the substrate 204 by applying photo sensitive agent through the different thickness of photoresist can be reduced as compared to the conventional techniques.

Step S103: removing portions of the dielectric layer, the first metal layer and the first semiconductor layer that are not covered by the first photoresist layer and making surface of portion of the dielectric layer corresponding to a thin area of the first photoresist layer exposed.

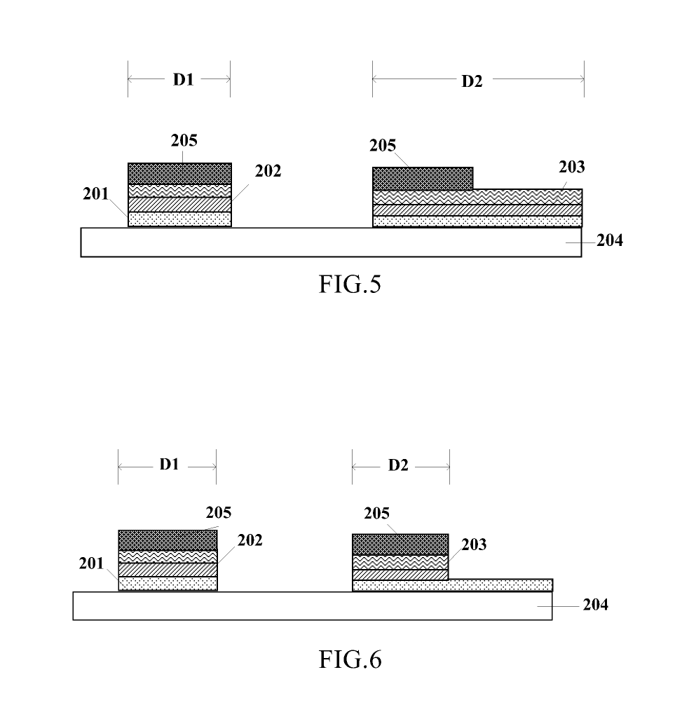

In Step S103, as shown in FIG. 4, the first photoresist layer 205 is used as an etching mask to carry out etching operation in order to remove the portions of the dielectric layer 201, the first metal layer 202 and the first semiconductor layer 203 that are not covered by the first photoresist layer 205. Then, oxygen is introduced to carry out ashing process in order to reduce the thickness of the first photoresist layer 205 to such an extent that the thin portion of the first photoresist layer 205 in the second zone D2 of Step S102 is completely removed (see FIG. 5). At this moment, the first photoresist layer 205 within the first zone D1 and the thick portion of first photoresist layer 205 within the second zone D2 are not reduced in thickness. By applying dry etching, a portion of the first metal layer 202 that is not covered by the first photoresist layer 205 in the second zone D2 is removed and then, by applying wet etching, a portion of the first semiconductor layer 203 that is not covered by the first photoresist layer 205 in the second zone D2 is removed (see FIG. 6).

Step S104: removing the first photoresist layer and sequentially forming a second semiconductor layer, a first protection layer, and a second metal layer on the substrate, in which the second metal layer is used to form TFT and gate line.

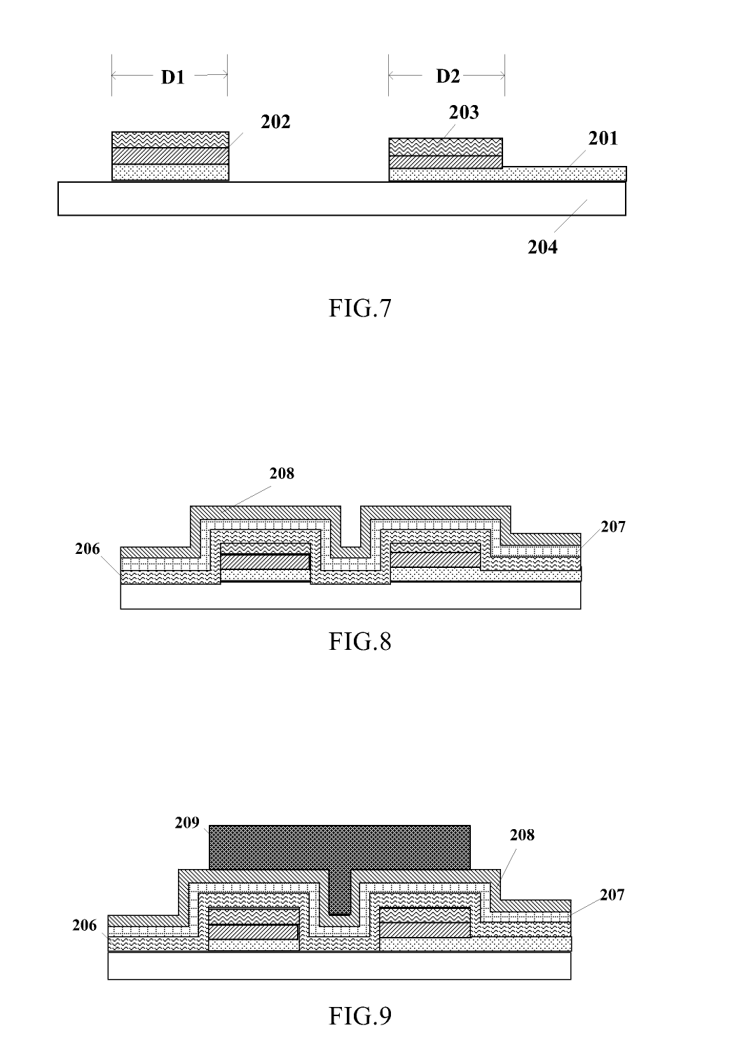

In Step S104, as shown in FIGS. 7 and 8, the second semiconductor layer 206 comprises an amorphous silicon layer doped with n+ impurity. The second metal layer 208 made of a metal, such as aluminum, molybdenum, titanium, chromium, copper, or an oxide of any of these metals, such as titanium oxide, or an alloy of these metals or other electrically conductive material, wherein the material used can be the same as or different from that of the first metal layer 202. After the formation of the second metal layer 208, etching is applied to form TFT and gate line. The method used to deposit the second metal layer 208 can be magnetron sputtering and etching can be wet etching. Magnetron sputtering is a deposition method performed by filling a proper amount of argon in high degree vacuum and applying several hundred K DC voltage to induce magnetron abnormal glow discharge in a coating chamber in order to cause ionization of argon. The argon ions are accelerated by cathode to impinge the surface of anode target so as to make atoms sputtering from the surface of the metal target material to deposit on a surface of the substrate, forming a thin film.

The first protection layer 207 can be made of a dielectric material, such a silicon nitride layer, a silicon oxide layer, or silicon oxynitride, and can be formed through chemical vapor deposition (CVD) or other film forming techniques. In the instant embodiment, chemical vapor deposition is a technique that is most commonly used in the semiconductor industry to deposit multiple materials, including a wide range of insulation materials, most metal materials and metal alloys. The main process is to introduce two or more gaseous raw materials into a reaction chamber to allow the two to take chemical reaction to form a new material that is then deposited on the surface of a chip. Deposition of silicon nitride (Si3N4) film is an example, which is formed through reaction between silane and nitrogen. Chemical vapor deposition is a conventional technique used to make thin film, of which the operation principle is allowing gaseous reaction precursors to under go chemical reaction between atoms and molecules in order to have a portion of the gaseous reaction precursors decomposed and deposited on the substrate to form a thin film. Chemical vapor deposition includes normal pressure chemical vapor deposition, plasma assisted chemical deposition, laser assisted chemical deposition, and metal organic compound deposition.

Step S105: forming a second photoresist layer on a portion of the second metal layer corresponding to the TFT and gate line.

In Step S105, as shown in FIG. 9, after the formation of the second metal layer 208, a second photoresist layer 209 is formed on a portion of the second metal layer 208 corresponding to the TFT and gate line, the second photoresist layer 209 covering the channel, the source, and the drain.

Step S106: except the dielectric layer at one side, removing all layers on the substrate that are covered by the second photoresist layer.

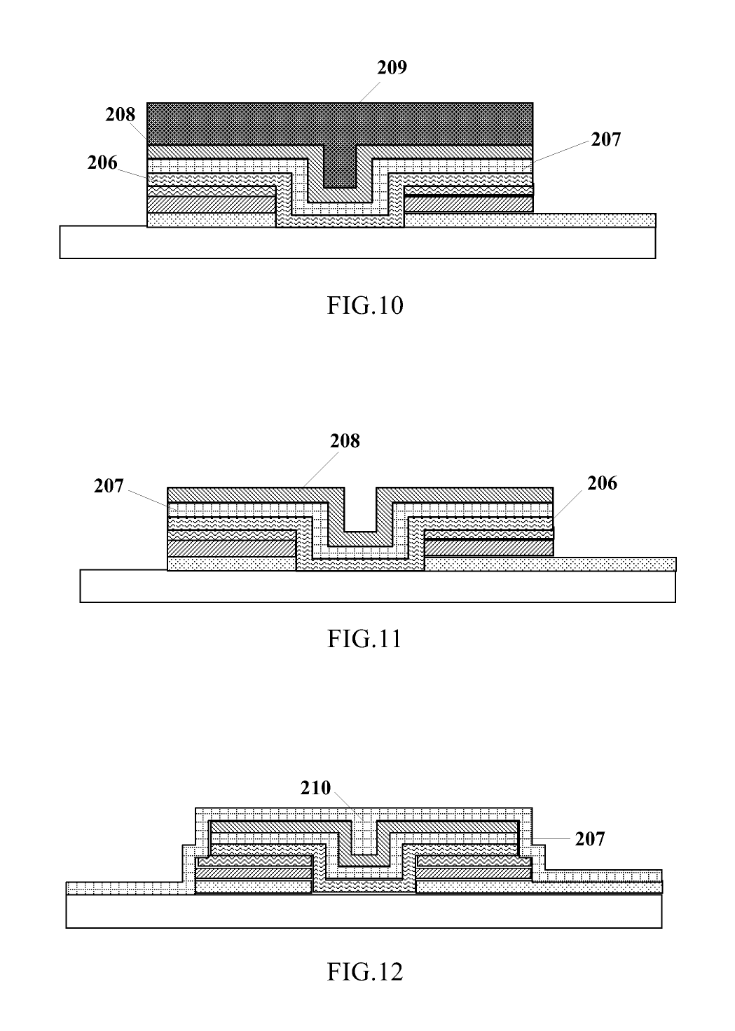

In Step S106, as shown in FIG. 10, using the second photoresist layer 209 as an etching mask to carry out an etching operation by which all the layers that are not covered by the second photoresist layer 209, these layers including: the second semiconductor layer 206, the first protection layer 207, and the second metal layer 208.

Step S107: removing the second photoresist layer and forming a second protection layer on the substrate.

In Step S107, as shown in FIG. 11, a regular masking process is adopted to perform exposure on the second photoresist layer 209 and then the second photoresist layer 209 is removed. As shown in FIG. 12, after the removal of the second photoresist layer 209, the second protection layer 210 is formed on and covers the substrate 204. The second protection layer 210 can be made of a dielectric material, such a silicon nitride layer, a silicon oxide layer, or silicon oxynitride, and can be formed through chemical vapor deposition or other film forming techniques. The material used can be the same as or different from that of the first protection layer 207.

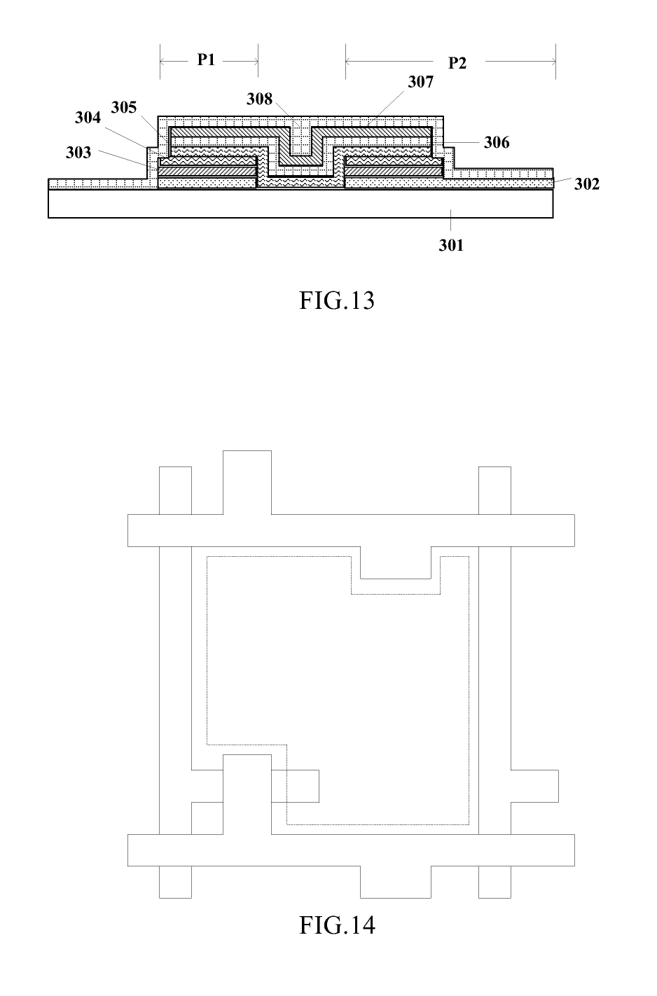

FIG. 13 is a cross-sectional view showing the structure of a TFT substrate according to an embodiment of the present invention. As shown in FIG. 13, the TFT substrate according to the embodiment comprises: a dielectric layer 302, a first metal layer 303, a first semiconductor layer 304, a second semiconductor layer 305, a first protection layer 306, a second metal layer 307, and a second protection layer 308.

The dielectric layer 302 is formed on the substrate 301 and comprises a first zone dielectric layer P1 and a second zone dielectric layer P2. The first zone dielectric layer P1 and the second zone dielectric layer P2 form therebetween a channel (not shown). The first metal layer 303 is formed on the dielectric layer 302. The first semiconductor layer 304 is formed on the first metal layer 303. The second semiconductor layer 305 is formed on the first semiconductor layer 304 and the channel. The first protection layer 306 is formed on the second semiconductor layer 305. The second metal layer 307 is formed on the first protection layer 306. The second protection layer 308 covers the second metal layer 307 and a portion of the surface of the substrate 301 outside the second metal layer 307.

In the instant embodiment, the dielectric layer 302, the first metal layer 303, the first semiconductor layer 304, the second semiconductor layer 305, the first protection layer 306, the second metal layer 307 and the second protection layer 308 are respectively made of the same materials as those of the counterparts of the previous embodiment, so that repeated description will be omitted.

FIG. 14 is a schematic plan view of a pixel included in the TFT substrate according to the present invention.

According to another embodiment of the present invention, a liquid crystal display device is provided, comprising: a color filter substrate and a TFT substrate.

The color filter substrate and the TFT substrate are arranged parallel to and spaced from each other. The TFT substrate can be a TFT substrate according to any one of the previously discussed embodiments and further description will be omitted.

The present invention uses only two masking processes of half-toning and regular mask so that the number of masking process is reduced and the manufacturing of thin-film transistor substrate is greatly simplified.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A method for manufacturing thin-film transistor (TFT) substrate, characterized by comprising:
sequentially depositing a dielectric layer, a first metal layer, and a first semiconductor layer on a substrate;
applying half-toning technique to form a thickness variable first photoresist layer on the first semiconductor layer;
removing portions of the dielectric layer, the first metal layer and the first semiconductor layer that are not covered by the first photoresist layer and making surface of portion of the dielectric layer corresponding to a thin area of the first photoresist layer exposed;
removing the first photoresist layer and sequentially forming a second semiconductor layer, a first protection layer, and a second metal layer on the substrate, in which the second metal layer is used to form TFT and gate line;
forming a second photoresist layer on a portion of the second metal layer corresponding to the TFT and gate line;
removing all layers on the substrate that are covered by the second photoresist layer except the dielectric layer at one side; and
removing the second photoresist layer and forming a second protection layer on the substrate.

2. The method as claimed in claim 1, characterized in that:
the step of applying half-toning technique to form a thickness variable first photoresist layer on the first semiconductor layer comprises:
applying half-toning to a first zone of the first photoresist layer and a second zone of the first photoresist layer that are spaced on the first semiconductor layer, wherein the first photoresist layer of the second zone has variable thickness.

3. The method as claimed in claim 2, characterized in that:
the step of removing portions of the dielectric layer, the first metal layer and the first semiconductor layer that are not covered by the first photoresist layer comprises:
etching off portions of the dielectric layer, the first metal layer and the first semiconductor layer that are not covered by the first zone and the second zone of the first photoresist layer;
performing ashing operation to such an extent that a thin portion of the first photoresist layer in the second zone is removed; and
sequentially performing dry etching and wet etching to remove portions of the first metal layer and the first semiconductor layer that are not covered by the first photoresist layer in the second zone to expose a corresponding portion of the dielectric layer.

4. The method as claimed in claim 1, characterized in that:
the step of removing all layers on the substrate that are covered by the second photoresist layer except the dielectric layer at one side comprises:
except the dielectric layer at one side, removing all layers that not covered by the second photoresist layer on the substrate by sequentially applying wet etching and dry etching.

5. The method as claimed in claim 1, characterized in that:
the dielectric layer is an indium tin oxide glass layer, the first semiconductor layer is an amorphous silicon layer doped with n+ impurity, the second semiconductor layer is an amorphous layer, and the first protection layer and the second protection layer are both silicon nitride layers.

6. A thin-film transistor (TFT) substrate, characterized by comprising:
a dielectric layer, which is formed on the substrate and comprises a first zone dielectric layer and a second zone dielectric layer, the first zone dielectric layer and the second zone dielectric layer forming therebetween a channel;
a first metal layer, which is formed on the dielectric layer;
a first semiconductor layer, which is formed on the first metal layer;
a second semiconductor layer, which is formed on the first semiconductor layer and the channel;
a first protection layer, which is formed on the second semiconductor layer;
a second metal layer, which is formed on the first protection layer; and
a second protection layer, which covers the second metal layer and a surface of the substrate outside the second metal layer.

7. The substrate as claimed in claim 6, characterized in that:
the dielectric layer is an indium tin oxide glass layer.

8. The substrate as claimed in claim 7, characterized in that:
the first semiconductor layer is an amorphous silicon layer doped with n+ impurity and the second semiconductor layer is an amorphous layer.

9. The substrate as claimed in claim 6, characterized in that:
the first protection layer and the second protection layer are both silicon nitride layers.

10. A liquid crystal display device, which comprises a color filter substrate and a thin-film transistor substrate that are substantially parallel and spaced, characterized in that the thin-film transistor substrate comprises:
a substrate;
a dielectric layer, which is formed on a surface of the substrate adjacent to the color filter substrate and comprises a first zone dielectric layer and a second zone dielectric layer, the first zone dielectric layer and the second zone dielectric layer forming therebetween a channel;
a first metal layer, which is formed on the dielectric layer;
a first semiconductor layer, which is formed on the first metal layer;
a second semiconductor layer, which is formed on the first semiconductor layer and the channel;
a first protection layer, which is formed on the second semiconductor layer;
a second metal layer, which is formed on the first protection layer; and
a second protection layer, which covers the second metal layer and a surface of the substrate outside the second metal layer.

11. The liquid crystal display device as claimed in claim 10, characterized in that:
the dielectric layer is an indium tin oxide glass layer.

12. The liquid crystal display device as claimed in claim 11, characterized in that:
the first semiconductor layer is an amorphous silicon layer doped with n+ impurity and the second semiconductor layer is an amorphous layer.

13. The liquid crystal display device as claimed in claim 10, characterized in that:
the first protection layer and the second protection layer are both silicon nitride layers.
